(19) United States
(12) Patent Application Publication
(10) Pub. No.: US 2010/0096003 A1
(43) Pub. Date: Apr. 22, 2010

(54) Article of manufacture for a magnetically induced photovoltaic solar cell device and the process for creating the magnetic and/or electromagnetic field

(76) Inventor: Dale James Hobbie, Weeki Wachee, FL (US)

Correspondence Address: Dale James Hobbie, 10113 Holly Berry Drive, Weeki Wachee, FL, 34613-3415, US

(21) Appl. No.: 12/378,097

(22) Filed: Feb. 11, 2009

Related U.S. Application Data
(60) Provisional application No. 61/196,864, filed on Oct. 21, 2008.

(51) Int. Cl. H01L 31/02

(52) U.S. Cl. 136/254

(57) ABSTRACT

An article of manufacture for a magnetically induced photovoltaic solar cell device and the process for creating the magnetic and/or electromagnetic field(s) utilizing a basal underlying structure consisting of the body of any and all types of photovoltaic solar cell devices within which a magnetic and/or electromagnetic field will be created and/or generated through the overlayment of the previously mentioned photovoltaic device structure with a magnetic inducement layer and/or coating which is comprised of a carrier/binding medium and magnetic particle inclusions. The addition of the magnetic inducement layer serves the specific purpose of creating and/or generating greater photon and electron excitement, retention and absorption within the crystalline matrix of the underlying photovoltaic solar cell device.

### CROSS REFERENCE TO RELATED APPLICATIONS

This application is based on provisional application Ser. No. 61/196,864, filed on Oct. 21, 2008.

### STATEMENT REGARDING FEDERALLY SPONSORED RESEARCH OR DEVELOPMENT

Not Applicable

### DESCRIPTION OF ATTACHED APPENDIX

Not Applicable

### BACKGROUND OF THE INVENTION

This invention relates generally to the field of photovoltaic devices and more specifically to an article of manufacture for a magnetically induced photovoltaic solar cell device and the process for creating the magnetic and/or electromagnetic field. Photovoltaics have been around for over 170 years when a French physicist discovered the photovoltaic effect while experimenting with electrodes and electrolytes in the presence of direct sunlight. Since that time numerous advances in technology have occurred, not only within the structural matrix of photovoltaic solar cell devices, but also in relation to the materials that are utilized within that structural matrix.

We have seen the development of new technology solar cells utilizing single crystalline and multicrystalline forms of selenium, silicon, germanium, cadmium-telluride and gallium-arsenide. We have seen the utilization of numerous conductive metals and alloys, including aluminum, copper, silver, tin and zinc as a means to more readily transfer the generated electrical current within and without the photovoltaic solar cell devices themselves. We have also seen the development of thin-film technologies and crystalline nano-structures that allow for the production of photovoltaic building materials, paints and even extremely thin adhesive layers that can be applied to glass.

The primary focus of the advancement of the technology throughout its history has been to increase efficiency levels and decrease costs associated with the production of photovoltaic solar cell devices that are being produced for use not only on a commercial scale, but also on a residential level, thereby allowing homeowners to take greater control of their monthly and annual utility expenses. Efficiency levels began in the early 1800's at a level of less than one percent (1%) and today the average silicon based photovoltaic solar cell device (most common) realizes an efficiency rating of approximately fifteen percent (15%). This doesn't take into consideration some of the exotic combinations of technologies that can sporadically create efficiency levels exceeding forty-five percent (45%). Consistently higher efficiency photovoltaics have been, and will continue to be, the primary focus of all participants within the solar energy and renewable energy sectors.

Previous patents and inventions relating to photovoltaics have moved us forward through the history of the industry, with most of the greatest innovations occurring within the past twenty (20) years. In 1918 a polish scientist by the name of Czochralski developed and patented a way to grow single crystalline silicon, a technology that is still the primary basis for the majority of the silicon which is used within the photovoltaics industry today. Albert Einstein received a Nobel Prize in 1923 for his theories explaining the photoelectric effect and the ramifications that it could have on technology. Efficiency would be the key.

In 1954 it was discovered at RCA's labs that cadmium (Cd) had incredible photoelectric properties. That same year engineers at Bell Labs created silicon solar cells that reached an efficiency level of 4.5%, which was subsequently increased to 6% a few months later, a record efficiency level at that time. The following year the first commercial licenses were being sold for silicon technologies by Western Electric. Unfortunately the efficiency level of commercial solar applications was only at 2%, causing the price of solar energy to be almost $1500 per watt. Throughout the 1950's the technology continued to advance and efficiency levels continued to climb, with the year 1960 bringing us an efficiency level of 14% thanks to Hoffman Electronics. Efficiency and cost effectiveness are once again serious issues.

In 1961 the UN conference on Solar Energy in the Developing World took place. By 1963 the Japanese had installed a 242 watt solar array into service, which was the largest to date. The 1960's continued to provide advances in technology as well, including, ribbon growing technologies, 1 kW arrays and the use of cadmium-sulfide (CaS) solar cells on an orbital satellite. Unfortunately efficiency and cost were still an ongoing concern that was creating roadblocks.

The 1970's and 1980's brought about energy crisis situations in various parts of the world and the demand for alternative sources of energy created even greater emphasis being place on solar energy research and development, for the benefit of us all. Advances in ribbon technology, arrays sizes and commercial advances in photovoltaic production and manufacturing pushed to the forefront of the day. In the 1990's the US government became a key player in the advancement of technology by opening the National Renewable Energy Labs in Golden, Colo. and beginning the funding of private research projects. Efficiency and cost reduction were again the primary focus of most, if not all, research and development projects.

From the late 1990's through the present advancement of technology relating to crystalline structures, composition and production drive the markets. However, efficiency continues to be the primary focus of new technology research and is the driving focus behind for our magnetic inducement technology.

The fact that magnetics have never truly been considered as a fundamental catalyst for an increase in efficiency brings us to our current patent application. Most of the prior technologies can be utilized as building and stumbling blocks for our magnetic inducement technology, with our technology providing a very low cost, effective and prudent development in field of cost effective efficiency level increases within the photovoltaic solar cell device industry.

The deficiencies in the prior technologies relating to photovoltaics and solar energy/photon/electron attraction and capture have continued to be based upon inefficient methods. Our magnetic inducement technology provides the vehicle through which these deficiencies of efficiency can be overcome, not to mention that we are providing a simple level of modification to a technology that currently does not meet the needs of the industry.

It is well known in the realm of physics that not only does electricity create/generate a magnetic field, likewise a magnetic field creates/generates an electric field. Bearing this in mind, when you take any of the current photovoltaic solar cell device technology and add our magnetic inducement feature to it, the resulting modified product will be enabled to produce nothing less than a higher efficiency device. We utilize the most fundamental of techniques, including naturally occurring magnetic materials which provide the highest remenence and orsted levels that can be found, thereby providing the longest lasting magnetic moments. This in turn allows for a continual magnetic field to be created/generated, without any additionally required energy input, likewise providing for the greater molecular excitation of photons and electrons within the crystalline matrix of the semiconductive material layers found within a photovoltaic solar cell device which has been modified with our magnetic inducement layer.

The simplicity of this magnetic inducement layer/coating provides that it can be applied to new production photovoltaic solar cells, already produced and warehoused photovoltaic solar cells, and/or already installed photovoltaic solar cells. The carrier/binder variables, and the variety of application processes thereof, allow for the implementation of numerous means and methods in order to apply, dry and cure the magnetic inducement layer/coating under a myriad of situations, with a focus on the end use product requirements.

The benefits of enhancing the current inefficient photovoltaic technology that exists today has never been more prevalent, especially taking into consideration those road blocks which present themselves daily based upon the current energy situations that are being experiencing within the non-renewable energy and fossil fuels sectors. Advancement of current photovoltaic technology is the only factor that will bring forth the necessary changes in order to generate the awareness that alternative, sustainable and renewable energy sources must be located, improved and refined to allow for the lowest cost, highest efficiency and most consistent generation of power for the masses.

Again, magnetic fields create/generate their own electrical fields, and electrical fields create/generate their own magnetic fields, these two most basic of physical attributes were made for each other, and our article of manufacture and associated processes bring the most basic of fundamentals from both technologies together within a much needed advancement in technology for photovoltaic solar cell devices.

### BRIEF SUMMARY OF THE INVENTION

The primary object of the invention is to competently and economically facilitate a non-labor intensive and more efficient process for converting a greater number of photons into electrical energy.

Another object of the invention is to competently and economically facilitate a non-labor intensive and efficient process to manufacture a magnetically induced photovoltaic solar cell device which is more efficient than non-magnetically induced photovoltaic solar cell devices.

Another object of the invention is to competently and economically facilitate a non-labor intensive and efficient process that advantageously modifies lower efficiency photovoltaic solar cell devices, thereby creating a higher efficiency photovoltaic solar cell device.

A further object of the invention is to competently and economically facilitate a non-labor intensive and efficient process that advantageously modifies a higher efficiency photovoltaic solar cell device, thereby creating an even higher efficiency photovoltaic solar cell device.

Yet another object of the invention is to competently and economically facilitate the efficient generation of a magnetic and/or electromagnetic inductance field within the structural matrix of a photovoltaic solar cell device.

Still yet another object of the invention is to competently and economically facilitate the magnetically induced greater excitation of photons and electrons within the structural matrix of a photovoltaic solar cell device.

Another object of the invention is to competently and economically facilitate a magnetically induced longer retention period (time based) for the attraction and absorption of photons and electrons within the structural matrix of a photovoltaic solar cell device.

Another object of the invention is to competently and economically facilitate the magnetically induced greater retention of photons and electrons within the structural matrix of a photovoltaic solar cell device.

A further object of the invention is to competently and economically facilitate the more efficient, successful and constant diffusion of electrons within the structural matrix of a photovoltaic solar cell device, via the magnetic inducement thereof.

Yet another object of the invention is to competently and economically facilitate a more successful and constant diode relationship to promote electrical current flow within the structural matrix of a photovoltaic solar cell device, via the magnetic inducement thereof.

Still yet another object of the invention is to competently and economically facilitate a more successful and efficient transfer of photons and electrons across the p-n junction(s) within the structural matrix of a photovoltaic solar cell device, via the magnetic inducement thereof.

Another object of the invention is to competently and economically facilitate a more successful and efficient transfer of photons and electrons across the p-i-n junction(s) within the structural matrix of a photovoltaic solar cell device, via the magnetic inducement thereof.

Another object of the invention is to competently and economically produce a greater number of electron-hole pairs within the structural matrix of a photovoltaic solar cell device, via the magnetic inducement thereof.

A further object of the invention is to competently and economically facilitate a more efficient electrical current flow into the front surface field located within the structural matrix of a photovoltaic solar cell device, via the magnetic inducement thereof.

Yet another object of the invention is to competently and economically facilitate a more efficient electrical current flow into the back surface field located within the structural matrix of a photovoltaic solar cell device, via the magnetic inducement thereof.

Still yet another object of the invention is to competently and economically facilitate the more efficient electrical circuitry within the structural matrix of a photovoltaic solar cell device, via the magnetic inducement thereof.

Another object of the invention is to competently and economically facilitate the production and manufacture of a more efficient photovoltaic solar cell device to be utilized within the photovoltaic solar module industry.

Other objects and advantages of the present invention will become apparent from the following descriptions, taken in connection with the accompanying drawings, wherein, by way of illustration and example, an embodiment of the present invention is disclosed.

In accordance with a preferred embodiment of the invention, there is disclosed an article of manufacture for a magnetically induced photovoltaic solar cell device and the process for creating the magnetic and/or electromagnetic field comprising: a basal underlying structure consisting of the body of any and all photovoltaic solar cell devices which are comprised of, but not limited to, conductive materials such as aluminum (Al), silver (Ag), tin (Sn), copper (Cu), zinc (Zn), ferrites (Fe) (all variations) as well as any and all other conductive materials which have been, or may be in the future, determined to be of beneficial interest to the photovoltaic industry; a basal underlying structure consisting of the body of any and all photovoltaic solar cell devices which are comprised of, but not limited to, semiconductive materials such as silicon (Si) (all variations), sulfur and/or sulfides (S), copper (Cu), indium (In), gallium (Ga), arsenide (As), germanium (Ge), cadmium (Cd), tellurium or tellurides (Te), and/or any combinations thereof, as well as any and all other semiconductive materials which have been, or may be in the future, determined to be of beneficial interest to the photovoltaic industry, and/or any combinations thereof; any and all back surface overlay of a magnetic inducement layer and/or coating comprised of a carrier/binding medium and magnetic particle inclusions; a carrier/binding medium comprised of, but not limited to, polymers, plastics, epoxies, acrylics, silicones, other synthetic materials and inks, and/or any combination thereof, as well as any and all other carrier/binding materials which have been, or may be in the future, determined to be of beneficial interest to the photovoltaic industry; and magnetic particle inclusions, as contained within the carrier/binding medium, in the form of, but not limited to, all ferromagnetic materials (Fe) (and all variations thereof), all rare-earth or lanthanide materials, aluminum (Al) (and all variations thereof), nickel (Ni) (and all variations thereof), cobalt (Co) (and all variations thereof), gallium (Ga), magnesium (Mn), arsenide (As), and/or any and all ceramic variations thereof, and/or any and combinations or alloys thereof.

In accordance with a preferred embodiment of the invention, there is disclosed a process for a magnetically induced photovoltaic solar cell device and the process for creating the magnetic and/or electromagnetic field comprising the steps of: a basal underlying structure consisting of the body of any and all photovoltaic solar cell devices which are comprised of, but not limited to, conductive materials such as aluminum (Al), silver (Ag), tin (Sn), copper (Cu), zinc (Zn), ferrites (Fe) (all variations) as well as any and all other conductive materials which have been, or may be in the future, determined to be of beneficial interest to the photovoltaic industry; a basal underlying structure consisting of the body of any and all photovoltaic solar cell devices which are comprised of, but not limited to, semiconductive materials such as silicon (Si) (all variations), sulfur and/or sulfides (S), copper (Cu), indium (In), gallium (Ga), arsenide (As), germanium (Ge), cadmium (Cd), tellurium or tellurides (Te), and/or any combinations thereof, as well as any and all other semiconductive materials which have been, or may be in the future, determined to be of beneficial interest to the photovoltaic industry; and/or any combinations thereof; any and all back surface overlay and/or coating the basal underlying structure, consisting of photovoltaic solar cell device, with a magnetic inducement layer and/or coating comprised of a carrier/binding medium and magnetic particle inclusions, the utilization of a carrier/binding medium comprised of, but not limited to, polymers, plastics, epoxies, acrylics, silicones, other synthetic materials and inks, and/or any combination thereof, as well as any and all other carrier/binding materials which have been, or may be in the future, determined to be of beneficial interest to the photovoltaic industry, and the utilization of magnetic particle inclusions, as contained within the carrier/binding medium, in the form of, but not limited to, all ferromagnetic materials (Fe) (and all variations thereof), all rare-earth or lanthanide materials, aluminum (Al) (and all variations thereof), nickel (Ni) (and all variations thereof), cobalt (Co) (and all variations thereof), gallium (Ga), magnesium (Mn), arsenide (As), and/or any and all ceramic variations thereof, and/or any and combinations or alloys thereof.

### BRIEF DESCRIPTION OF THE DRAWINGS

The drawings constitute a part of this specification and include exemplary embodiments to the invention, which may be embodied in various forms. It is to be understood that in some instances various aspects of the invention may be shown exaggerated or enlarged to facilitate an understanding of the invention.

FIG. 1 is a cross sectional view of the invention based upon a homojunction device.

FIG. 2 is a cross sectional view of the invention based upon a heterojunction device.

FIG. 3 is a cross sectional view of the invention based upon a “p-i-n” or “n-i-p” device.

FIG. 4 is a cross sectional view of the invention based upon a multijunction device.

FIG. 5 is a schematic diagram illustrating the layering/coating application area of a portion of the invention.

FIG. 6 is a schematic diagram illustrating the layering/coating application area of a portion of the invention.

FIG. 7 is an elevational view of the invention based upon all photovoltaic solar cell device types.

### DETAILED DESCRIPTION OF THE PREFERRED EMBODIMENTS

Detailed descriptions of the preferred embodiment are provided herein. It is to be understood, however, that the present invention may be embodied in various forms. Therefore, specific details disclosed herein are not to be interpreted as limiting, but rather as a basis for the claims and as a representative basis for teaching one skilled in the art to employ the present invention in virtually any appropriately detailed system, structure or manner.

In keeping with the fundamentals of the article of manufacture for a Magnetically Induced Photovoltaic Solar Cell Device and the process for creating the magnetic and/or electromagnetic field consisting therewith, therein and/or thereon, as well as may be more fully disclosed and/or incorporated herewith and/or herein, an explanation of the concept, design, detail and utilization is provided as follows for the present and future beneficial interest of the photovoltaics industry:

Photons in sunlight hit the photovoltaic solar cell device and are absorbed by the semiconducting material(s) contained within the n-layer(s) of the photovoltaic solar cell device. Negatively charged electrons are then knocked loose from their atoms, allowing them to flow freely within and through this semiconducting material. The complementary positive charges that are also created flow in the direction opposite of the electrons and into the p-layer(s) of the semiconducting materials.

When photons enter the device, one or all of the following things/steps can happen:
a. The photon can pass straight through the semiconducting material(s);
b. The photon can reflect off the surface of the device; and/or
c. The photon can be absorbed by the semiconducting material, if the photovoltaic solar cell device, as this inclusion helps to generate an increased number of electron-hole pairs, depending upon the band width and structure.

When a photon is absorbed, its energy is given to an electron within the structural lattice of the semiconducting material(s). This electron is usually in the valence band, and is tightly bound in covalent bonds between its neighboring atoms, and hence it is unable to move far.

The energy given to it by the added electro-magnetic field “excites” more photons into the conduction band, where they are free to move around within the semiconducting material(s). The covalent bond that the electron was previously a part of now has one fewer electron, which is known as a “hole”. The presence of a missing covalent bond allows the bonded electrons of neighboring atoms to move into the created “hole”, leaving another “hole” behind, and in this way a “hole” can move through the structural lattice virtually unabated. Thus, it can be said that photons absorbed in the semiconducting material(s) create mobile electron-hole pairs. Once the magnetic and/or electromagnetic field is added it serves to further excite the photons and electrons within this scenario, thereby exponentially increasing the number of additional electron-hole pairs.

It is widely held that a photon need only have greater energy than that of the band gap in order to excite an electron from the valence band into the conduction band. However, the solar frequency spectrum approximates a black body spectrum at ˜6000 K, and as such, much of the solar radiation reaching the Earth is composed of photons with energies greater than the band gap of silicon. These higher energy photons will be absorbed by the photovoltaic solar cell device, but the difference in energy between these photons and the semiconducting materials' band gap is converted into heat rather than into usable electrical energy. By placing the magnetic and/or electromagnetic field inducement into the equation the photon and/or electron gathering ability of a magnetically induced photovoltaic solar cell device should consistently be greater than that of a conventional non-magnetically and/or non-electromagnetically induced photovoltaic solar cell device.

The magnetically induced homojunction photovoltaic solar cell devices are configured as large-area p-n junctions, which are made primarily, but not always from crystalline semiconducting material(s). As an over-simplification, you can imagine bringing a layer of n-type semiconducting material into direct contact with a layer of p-type semiconducting material. In reality however, the n-p junction(s) of the magnetically induced photovoltaic solar cell devices are not made in this way, but rather, by diffusing an n-type dopant into one side of a p-type layer (or vice versa). Under this application when the n-layer semiconducting material is placed in immediate contact with the p-layer semiconducting material, then the diffusion of electrons will occur from the region of the higher electron concentration, or the n-layer side of the junction into the region of the lower electron concentration, or the p-layer side of the junction. With the addition of the magnetic and/or electromagnetic inducement the electrons within the magnetically induced photovoltaic solar cell device should consistently diffuse more readily from the n-layer side across the n-p, p-n or p-i-n junction, where they will then recombine with holes within the p-layer side. This diffusion of carriers does not happen indefinitely however, because of an electrical field which is created by the imbalance of charges found immediately on either side of the junction which this diffusion creates. Therefore, continued exposure to additional photons is required to maintain constant electron transfer.

However, the introduction of the magnetic and/or electromagnetic field inducement from the Magnetic Inducement Layer/Coating should consistently extend the length and intensity of this diffusion. The magnetic and/or electromagnetic field that is established across the n-p, p-n or p-i-n junction creates a stronger diode that helps to promote an increased electrical current flow in only one direction across the junction. The excited electrons may pass more readily from the n-layer side into the p-layer side, and holes may pass more readily from the p-layer side to the n-layer side and vice versa.

Typically some form of an ohmic metal-semiconductor contact is made to both the n-layer side and the p-layer side of the magnetically induced photovoltaic solar cell, which therefrom connection is made to an external load or gathering device. Electrons that are created on the n-layer side, or have been absorbed or “collected” by the n-p, p-n or p-i-n junction and swept onto the n-type side, may travel through an electrically conductive material, providing power to the load or gathering device, and then continue through the electrically conductive material until they reach the p-layer semiconductor contact or electrode. Here, they recombine with a hole that was either created as an electron-hole pair on the p-layer side of the magnetically induced photovoltaic solar cell device, or swept across the junction from the n-layer side after being created there. This action summarily completes the electrically circuit for the electrical energy generation and transference which comprises the “Magnetically Induced Photovoltaic Solar Cell Device”.

The addition of the Magnetic Inducement Layer/Coating shall firstly serve the purpose of generating and/or creating magnetic and/or electromagnetic excitation of, and/or attraction of and/or induction of and/or promote the absorption of, photons and/or electrons within the n-layer(s), and/or the p-layer(s) and/or the n-p, p-n and/or p-i-n junction(s) as may be found within the structural matrix of any and all photovoltaic solar cell devices, as described below.

It is further evident that the addition of the Magnetic Inducement Layer/Coating shall additionally serve the purpose of creating a process by which to cost effectively increase the performance and efficiency levels of all such photovoltaic solar cell devices which would not be existent without the inclusion of such Magnetic Inducement Layer/Coating.

It is furthermore evident that the addition of the Magnetic Inducement Layer/Coating shall additionally serve the purpose of creating an additional protective backing layer/coating to the underlying structural matrix of a typical and standard photovoltaic solar cell device matrix, which upon modification incorporates within it a beneficial magnetic and/or electromagnetic inducement characteristic and/or facet.

A more detailed description of the specific structures, processes and applications of the Magnetically Induced Photovoltaic Solar Cell Device can be found within the text and drawings referenced below, as well as the processes and procedures for creating the Magnetic Inducement Layer/Coating as referenced heretofore and/or hereinafter:

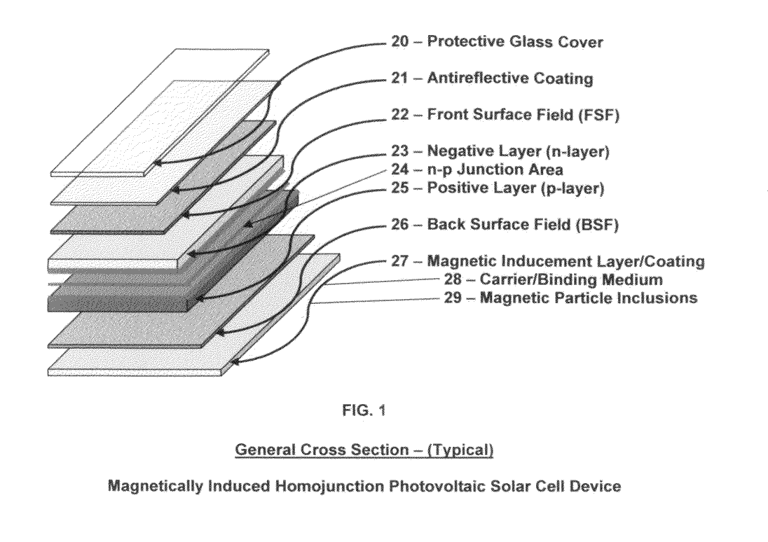

Beginning first with FIG. 1, there is shown a general cross section visual overview which encompasses the summary concept and structure of a magnetically induced homojunction photovoltaic solar cell device. The overall cell configuration is based upon the starting underlying basal structure of a common, typical and standard homojunction photovoltaic solar cell matrix utilizing various form(s), and/or variety(ies) and/or orientation(s) of semiconductive materials and/or wafers, such as, but not limited to, silicon. Such homojunction photovoltaic solar cell devices are typically comprised of a protective glass cover (FIG. 1, #20), an antireflective coating (FIG. 1, #21), a front surface field, or FSF, typically being comprised of, but not limited to, aluminum (Al) and or silver (Ag) (FIG. 1-#22) for the purpose of photon, electron and electrical energy transference, a layer of a negatively charged semiconductive material, such as, but not limited to, silicon (of varying molecular structure and orientation), known as the n-layer (FIG. 1, #23), an n-p junction area (FIG. 1, #24) which creates an area for the free transfer of electrons between the n-layer and p-layer, a layer of a positively charged semiconductive material, such as, but not limited to, silicon (of varying molecular structure and orientation, known as the p-layer (FIG. 1, #25), and a back surface field, or BSF, typically being comprised of, but not limited to aluminum (Al) and/or silver (Ag) and/or copper (Cu) and/or combinations or alloys thereof (FIG. 1, #26), which may or may not be contained within various substrates (dependent upon the manufacturer) and containing multiple conductive bus bars (of varying width and orientation) for the purpose of positive and or negative electrical energy transference and electrical circuit connection.

The variance from the common, typical and standard homojunction photovoltaic solar cell device is accomplished through the process of applying an additional Magnetic Inducement Layer/Coating (FIG. 1, #27) directly to the back surface area of a homojunction photovoltaic solar cell device, as described above within FIG. 1, which shall thereby cover the majority of the back surface area of such homojunction photovoltaic solar cell device with the Magnetic Inducement Layer/Coating (FIG. 1, #27). This Magnetic Inducement Layer/Coating (FIG. 1, #27) may or may not be resistant to heat, i.e. thermally resistant (dependent upon end use product requirements), may or may not be resistant to cold (dependent upon end use product requirements), may or may not be ultra-violet light resistant (dependent upon end use product requirements), may or may not be electrically conductive (dependent upon end use product requirements), shall consist of a Carrier/Binding Medium (FIG. 1, #28) which shall be comprised of, but not limited to, any and all polymers, plastics, epoxies, acrylics, silicones, other synthetics or inks and/or any combination thereof, which provides a carrier vehicle that encapsulates and binds the Magnetic Particle Inclusions (FIG. 1, #29) which shall be in the form of but not limited to, any and all ferromagnetic materials, any and all rare-earth or lanthanide materials, any and all alnico (aluminum-nickel-cobalt) materials, any and all gallium-manganese-arsenide (GaMnAs) materials, any and all ceramic incorporated/encapsulated variations thereof and/or any and all combination(s) and/or alloys thereof. These Magnetic Particle Inclusions (FIG. 1, #29) shall be comprised of singular and/or multiple, regular and/or irregular, consistent and/or inconsistent geometric shape(s), dependent upon the incorporated material type(s) and/or the end use product requirements. These Magnetic Particle Inclusions (FIG. 1, #29) shall be sized as may be required to facilitate the most efficient and/or available layering and/or coating method(s) as may be reasonably determined based upon the end product requirements and shall range from fifty nanometers (50 nm) up to and including 2 centimeters (2 cm) in size, dependent upon the Magnetic Particle Inclusion's type(s) and/or geometric structure and/or shape, and shall be incorporated and/or dispersed throughout and within said Carrier/Binding Medium (FIG. 1, #28) at a dispersion rate of between twenty-five percent (25%) and sixty percent (60%), by weight and/or volume, dependent upon the inclusion material's type, geometric structure and/or shape, size and end use product requirements.

This Magnetic Inducement Layer/Coating (FIG. 1, #27), inclusive of the Carrier/Binding Medium (FIG. 1, #28) and the Magnetic Particle Inclusions (FIG. 1, #29) shall be applied via overlaying it onto the underlying typical and standard homojunction photovoltaic solar cell device by means of various processing methods, including, but not limited to: a) any and all generally accepted, and/or typical, and/or standard, layering and/or coating application(s) and/or manufacturing process(es), i.e. screen printing, sputtering, spraying, brushing or spreading; and/or b) any and all specialized application and/or manufacturing method(s), and/or means, and/or process(es) as may have been already developed, and/or are yet to be developed, which will expedite the competent and efficient production and/or manufacturing of a magnetically induced silicon based photovoltaic solar cell. Such method(s), and/or means, and/or process(es) shall cause the direct and/or indirect application of the Magnetic Inducement Layer/Coating (FIG. 1, #27) to the non-illuminated side (back) of a common, typical and standard homojunction photovoltaic solar cell device, thereby bonding and/or binding the Carrier/Binding Medium (FIG. 1, #28) and the Magnetic Particle Inclusions (FIG. 1, #29) to such non-illuminated side (back) of a common, typical and standard homojunction photovoltaic solar cell device.

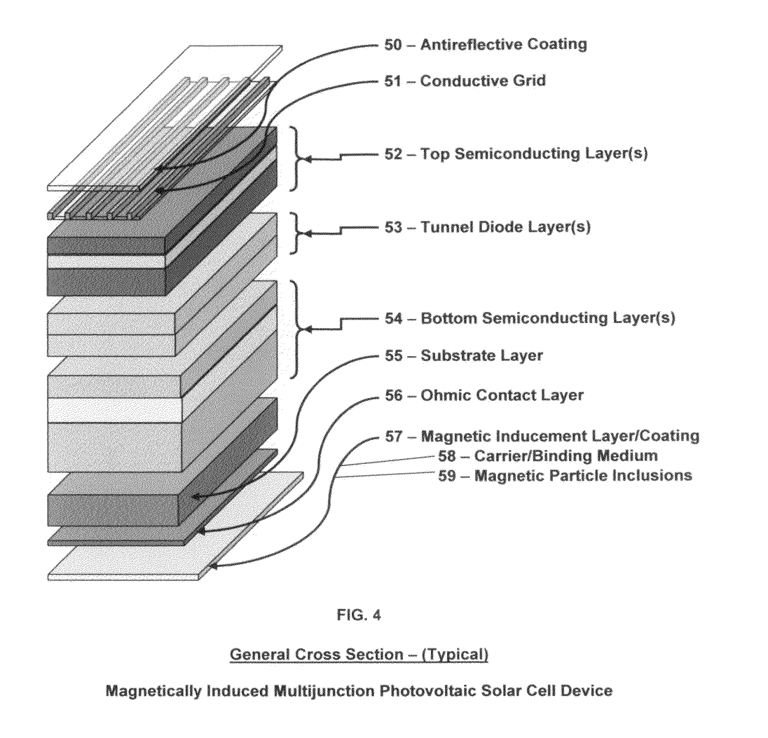

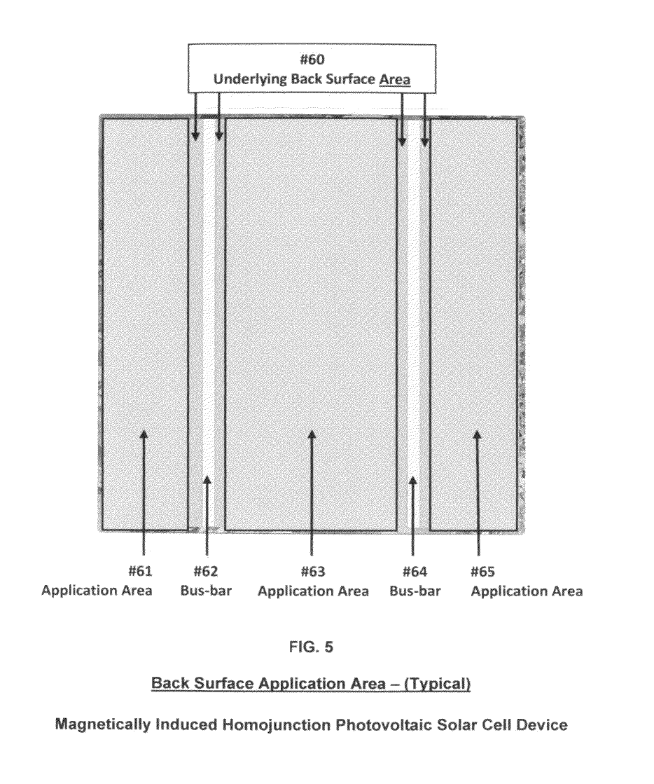

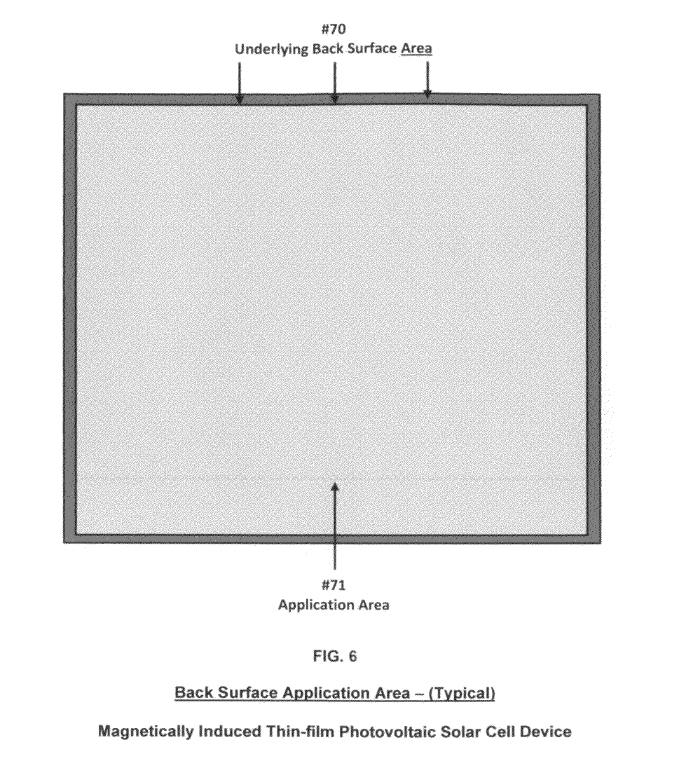

The aforementioned application of the Magnetic Inducement Layer/Coating (FIG. 1, #27) to a common, typical and standard homojunction photovoltaic solar cell device shall be reasonably accomplished consistent and/or pursuant to the outline and diagram provided within FIG. 4 and FIG. 5. The Back Surface Area (FIG. 5, #60) references only a portion of the total underlying area which commonly and/or typically comprises the entire back surface of a common, typical and standard homojunction photovoltaic solar cell device, whose BSF (FIG. 1, #26) incorporates within it bus-bars (FIG. 5, #62 and #64) which are utilized for further connection to an electrical circuit and the transference of positive and/or negative electrical energy from a common, typical and standard homojunction photovoltaic solar cell device. The Magnetic Inducement Layer/Coating (FIG. 1, #27) shall be typically applied to those areas defined as the Application Areas (FIG. 5, #61 and #63 and #65), to within up to one millimeter (1 mm) of the bus-bars (FIG. 6, #62 and #64), at a thickness of not less than 50 nanometers (50 nm) and not greater than two centimeters (2 cm), dependent upon the Magnetic Particle Inclusion material's type, geometric structure and/or shape and size.

The drying and/or curing time period requirements of the Magnetic Inducement Layer/Coating (FIG. 1, #27) shall be determined specifically by the Carrier/Binding Medium's (FIG. 1, #28) manufacturer's recommended drying and/or curing period(s), as well as the ambient temperature and/or relative humidity within the application and/or drying and/or curing areas of the production/manufacturing facility(ies).

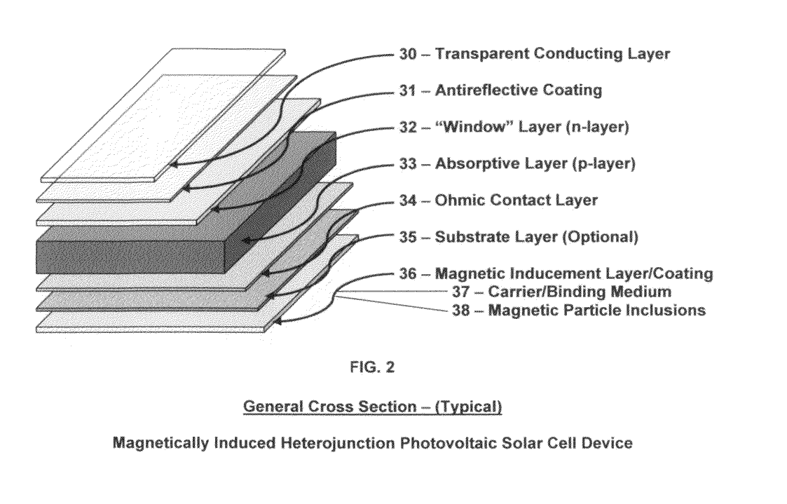

Turning now to FIG. 2, there is shown a general cross section visual overview which encompasses the summary concept and structure of a magnetically induced heterojunction photovoltaic solar cell device. The overall cell configuration is based upon the starting underlying basal structure of a common, typical and standard heterojunction photovoltaic solar cell matrix utilizing thin-film technology involving polycrystalline semiconductive materials, including, but not limited to, amorphous silicon, copper-indium-diselenide (CIS), and/or copper-indium-gallium-diselenide (CIGS), and/or gallium-arsenide (GaAs), and/or cadmium-telluride (CdTe) and/or any combination(s) thereof. Such heterojunction photovoltaic solar cell devices are typically comprised of various forms of a thin layer of a transparent conducting oxide layer, including, but not limited to, zinc oxide, (FIG. 2, #30); an antireflective coating (FIG. 2, #31); a thin negatively charged “window” layer (FIG. 2-#32), typically known as the n-layer, comprised of various types of semiconductive materials, including, but not limited to, cadmium-sulfide (CdS), with or without zinc added, which allows almost all available light to pass through its crystalline structure for the purpose of photon, electron and electrical energy interface with the sub-layers of the matrix; a positively charged highly absorptive layer (FIG. 2, #33), typically know as the p-layer, comprised of various types of semiconductive materials, including, but not limited to, copper-indium-diselenide (CIS), and/or copper-indium-gallium-diselenide (CIGS), and/or gallium-arsenide (GaAs), and/or any combination(s) thereof; an ohmic contact layer (FIG. 2, #34), typically comprised of, but not limited to, aluminum (Al), and/or tin (Sn), and/or copper (Cu), and/or any and all alloys thereof; and an optional substrate (dependent upon desired cell structure and the end use product requirements) which is comprised of various materials, including, but not limited to glass, plastics, metal alloys and composite structures.

The variance from the common, typical and standard heterojunction photovoltaic solar cell device matrix is accomplished through the process of applying an additional Magnetic Inducement Layer/Coating (FIG. 2, #36) directly to the back surface area of the Ohmic Contact Layer (FIG. 2, #34), and/or the Substrate Layer (FIG. 2, #35) (dependent upon end use product requirements), of a typical and standard heterojunction photovoltaic solar cell device, as described above within FIG. 2. Such Magnetic Inducement Layer/Coating (FIG. 2, #36) may or may not cover the majority, or the entirety, of the back surface area of such heterojunction photovoltaic solar cell device (dependent upon end use product requirements). This Magnetic Inducement Layer/Coating (FIG. 2, #36) may or may not be resistant to heat, i.e. thermally resistant (dependent upon end use product requirements), may or may not be resistant to cold (dependent upon end use product requirements), may or may not be ultra-violet light resistant (dependent upon end use product requirements), may or may not be electrically conductive (dependent upon end use product requirements), shall consist of a Carrier/Binding Medium (FIG. 2, #37) which shall be comprised of, but not limited to, any and all polymers, plastics, epoxies, acrylics, silicones, other synthetics or inks and/or any combination thereof, which provides a carrier vehicle that encapsulates and binds the Magnetic Particle Inclusions (FIG. 2, #38) which shall be in the form of, but not limited to, any and all ferromagnetic materials, any and all rare-earth or lanthanide materials, any and all alnico (aluminum-nickel-cobalt) materials, any and all gallium-manganese-arsenide (GaMnAs) materials, any and all ceramic incorporated/encapsulated variations thereof and/or any and all combination(s) and/or alloys thereof. These Magnetic Particle Inclusions (FIG. 2, #38) shall be comprised of singular and/or multiple, regular and/or irregular, consistent and/or inconsistent geometric shape(s), dependent upon the incorporated material type(s) and/or the end use product requirements. These Magnetic Particle Inclusions (FIG. 2, #38) shall be sized as may be required to facilitate the most efficient and/or available layering and/or coating method(s) as may be reasonably determined based upon the end product requirements and shall range from fifty nanometers (50 nm) up to and including 2 centimeters (2 cm) in size, dependent upon the Magnetic Particle Inclusion's type(s) and/or geometric structure and/or shape, and shall be incorporated and/or dispersed throughout and within said Carrier/Binding Medium (FIG. 2, #37) at a dispersion rate of between twenty-five percent (25%) and sixty percent (60%), by weight and/or volume, dependent upon the inclusion material's type, geometric structure and/or shape, size and end use product requirements.

This Magnetic Inducement Layer/Coating (FIG. 2, #36), inclusive of the Carrier/Binding Medium (FIG. 2, #37) and the Magnetic Particle Inclusions (FIG. 2, #38) shall be applied via overlaying it onto the underlying typical and standard heterojunction photovoltaic solar cell device by means of various processing methods, including, but not limited to: a) any and all generally accepted, and/or typical, and/or standard, layering and/or coating application(s) and/or manufacturing process(es), i.e. screen printing, sputtering, spraying, brushing or spreading; and/or b) any and all specialized application and/or manufacturing method(s), and/or means, and/or process(es) as may have been already developed, and/or are yet to be developed, which will expedite the competent and efficient production and/or manufacturing of a magnetically induced heterojunction photovoltaic solar cell. Such method(s), and/or means, and/or process(es) shall cause the direct and/or indirect application of the Magnetic Inducement Layer/Coating (FIG. 2, #36) to the non-illuminated side (back) of a common, typical and standard heterojunction photovoltaic solar cell device, thereby bonding and/or binding the Carrier/Binding Medium (FIG. 2, #37) and the Magnetic Particle Inclusions (FIG. 2, #38) to such non-illuminated side (back) of a common, typical and standard heterojunction photovoltaic solar cell device.

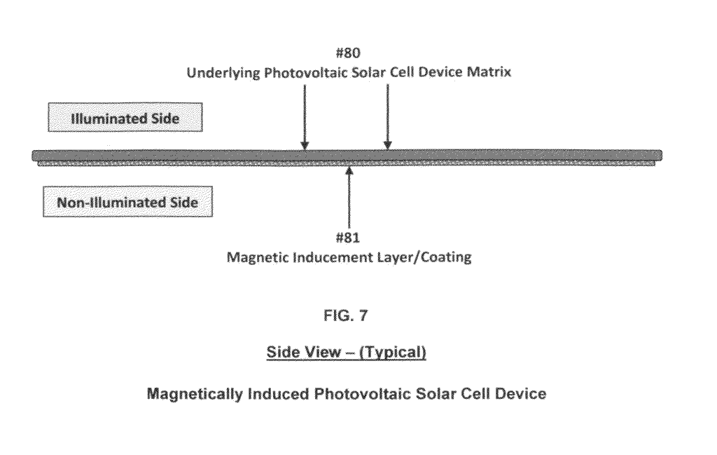

The aforementioned application of the Magnetic Inducement Layer/Coating (FIG. 2, #36) to a common, typical and standard heterojunction photovoltaic solar cell device shall be reasonably accomplished consistent and/or pursuant to the outline and diagram provided within FIG. 6 and FIG. 7. The Back Surface Area (FIG. 6, #70), references only a portion of the total Underlying Photovoltaic Solar Cell Device Matrix (FIG. 7, #80) which commonly and/or typically comprises the entire back surface of a common, typical and standard heterojunction photovoltaic solar cell device, which may, or may not, incorporate within its matrix, bus-bars and/or electrical leads which are utilized for further connection to an electrical circuit and the transference of positive and/or negative electrical energy from a common, typical and standard multijunction photovoltaic solar cell device. The Magnetic Inducement Layer/Coating (FIG. 2, #36) shall be typically applied to those areas defined as the Application Area (FIG. 6, #71), to within up to one millimeter (1 mm) of the edge of the typical and standard heterojunction photovoltaic solar cell device, at a thickness of not less than 50 nanometers (50 nm) and not greater than two centimeters (2 cm), dependent upon the Magnetic Particle Inclusion material's type, geometric structure and/or shape and size.

The drying and/or curing time period requirements of the Magnetic Inducement Layer/Coating (FIG. 2, #36) shall be determined specifically by the Carrier/Binding Medium's (FIG. 2, #37) manufacturer's recommended drying and/or curing period(s), as well as the ambient temperature and/or relative humidity within the application and/or drying and/or curing areas of the production/manufacturing facility(ies).

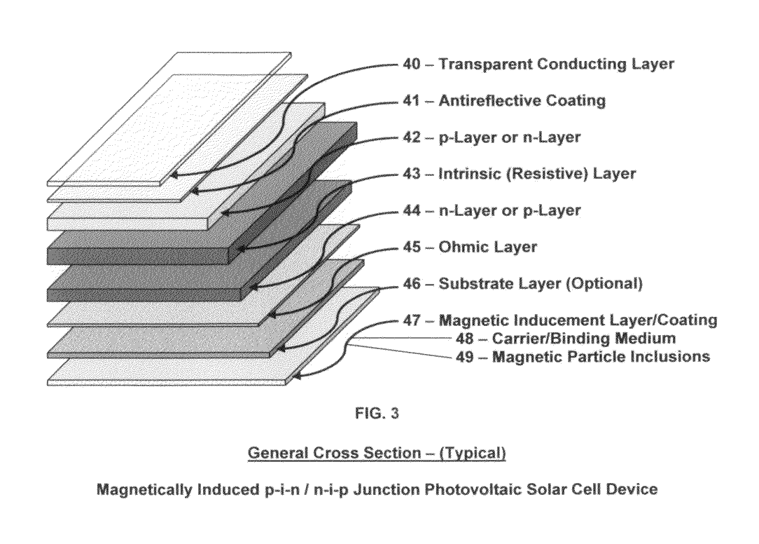

Turning now to FIG. 3, there is shown a general cross section visual overview which encompasses the summary concept and structure of a magnetically induced positive-intrinsic-negative (p-i-n) or negative-intrinsic-positive (n-i-p) junction photovoltaic solar cell device. The overall cell configuration is based upon the starting underlying basal structure of a common, typical and standard p-i-n or n-i-p junction photovoltaic solar cell matrix utilizing thin-film technology involving various semiconductive materials, including, but not limited to, amorphous silicon (a-Si), cadmium-telluride (CdTe) or gallium-arsenide (GaAs), and/or any combination(s) thereof. Such photovoltaic solar cell devices are typically comprised of various forms of a thin layer of a transparent conducting oxide layer, including, but not limited to, zinc oxide, (FIG. 3, #40); an antireflective coating (FIG. 3, #41); a positively charged p-Layer (positive-doped) or a negatively charged n-Layer (negative-doped) (FIG. 3-#42) (p and n doping is dependent upon desired cell structure and/or end use product requirements) and is typically known as the top layer, which is typically comprised of various types of semiconductive materials, including, but not limited to, those semiconductive materials described above; an intrinsic/resistive layer (un-doped, un-charged) (FIG. 3, #43), which is typically comprised of various types of semiconductive materials, including, but not limited to, those semiconductive materials described above, for the purpose of generating an electrical field between the p-layer and the n-layer to promote the flow of free electrons and electron-holes; a negatively charged n-layer (negative-doped) or a positively charged p-layer (positive-doped) (FIG. 3, #44) (p and n doping is dependent upon desired cell structure and/or end use product requirements) and is typically known as the bottom layer, which is typically comprised of various types of semiconductive materials, including, but not limited to, those semiconductive materials described above, with or without added components including, but not limited to, zinc (Zn) and/or tin (Sn); an ohmic contact layer (FIG. 3, #45), typically comprised of, but not limited to, aluminum (Al), and/or tin (Sn), and/or copper (Cu), and/or any and all alloys thereof; and an optional substrate (dependent upon desired cell structure and the end use product requirements) which is comprised of various materials, including, but not limited to glass, plastics, metal alloys and composite structures.

The variance from the common, typical and standard p-i-n or n-i-p junction photovoltaic solar cell device is accomplished through the process of applying an additional Magnetic Inducement Layer/Coating (FIG. 3, #47) directly to the back surface area of the Ohmic Contact Layer (FIG. 3, #45), and/or the Substrate Layer (FIG. 3, #46) (dependent upon end use product requirements), of a typical and standard p-i-n or n-i-p junction photovoltaic solar cell device, as described above within FIG. 3. Such Magnetic Inducement Layer/Coating (FIG. 3, #47) may or may not cover the majority, or the entirety, of the back surface area of such p-i-n or n-i-p junction photovoltaic solar cell device (dependent upon end use product requirements). This Magnetic Inducement Layer/Coating (FIG. 3, #47) may or may not be resistant to heat, i.e. thermally resistant (dependent upon end use product requirements), may or may not be resistant to cold (dependent upon end use product requirements); may or may not be ultra-violet light resistant (dependent upon end use product requirements), may or may not be electrically conductive (dependent upon end use product requirements), shall consist of a Carrier/Binding Medium (FIG. 3, #48) which shall be comprised of, but not limited to, any and all polymers, plastics, epoxies, acrylics, silicones, other synthetics or inks and/or any combination thereof, which provides a carrier vehicle that encapsulates and binds the Magnetic Particle Inclusions (FIG. 3, #49) which shall be in the form of, but not limited to, any and all ferromagnetic materials, any and all rare-earth or lanthanide materials, any and all alnico (aluminum-nickel-cobalt) materials, any and all gallium-manganese-arsenide (GaMnAs) materials, any and all ceramic incorporated/encapsulated variations thereof and/or any and all combination(s) and/or alloys thereof. These Magnetic Particle Inclusions (FIG. 3, #49) shall be comprised of singular and/or multiple, regular and/or irregular, consistent and/or inconsistent geometric shape(s), dependent upon the incorporated material type(s) and/or the end use product requirements. These Magnetic Particle Inclusions (FIG. 3, #49) shall be sized as may be required to facilitate the most efficient and/or available layering and/or coating method(s) as may be reasonably determined based upon the end product requirements and shall range from fifty nanometers (50 nm) up to and including 2 centimeters (2 cm) in size, dependent upon the Magnetic Particle Inclusion's type(s) and/or geometric structure and/or shape, and shall be incorporated and/or dispersed throughout and within said Carrier/Binding Medium (FIG. 3, #48) at a dispersion rate of between twenty-five percent (25%) and sixty percent (60%), by weight and/or volume, dependent upon the inclusion material's type, geometric structure and/or shape, size and end use product requirements.

This Magnetic Inducement Layer/Coating (FIG. 3, #47), inclusive of the Carrier/Binding Medium (FIG. 3, #48) and the Magnetic Particle Inclusions (FIG. 3, #49) shall be applied via overlaying it onto the underlying typical and standard p-i-n or n-i-p junction photovoltaic solar cell device by means of various processing methods, including, but not limited to: a) any and all generally accepted, and/or typical, and/or standard, layering and/or coating application(s) and/or manufacturing process(es), i.e. screen printing, sputtering, spraying, brushing or spreading; and/or b) any and all specialized application and/or manufacturing method(s), and/or means, and/or process(es) as may have been already developed, and/or are yet to be developed, which will expedite the competent and efficient production and/or manufacturing of a magnetically induced silicon based photovoltaic solar cell. Such method(s), and/or means, and/or process(es) shall cause the direct and/or indirect application of the Magnetic Inducement Layer/Coating (FIG. 3, #47) to the non-illuminated side (back) of a common, typical and standard p-i-n or n-i-p junction photovoltaic solar cell device, thereby bonding and/or binding the Carrier/Binding Medium (FIG. 3, #48) and the Magnetic Particle Inclusions (FIG. 3, #49) to such non-illuminated side (back) of a common, typical and standard heterojunction photovoltaic solar cell device.

The aforementioned application of the Magnetic Inducement Layer/Coating (FIG. 3, #47) to a common, typical and standard p-i-n or n-i-p junction photovoltaic solar cell device shall be reasonably accomplished consistent and/or pursuant to the outline and diagram provided within FIG. 6, and/or FIG. 7. The Back Surface Area (FIG. 6, #70), references only a portion of the total Underlying Photovoltaic Solar Cell Device Matrix (FIG. 7, #80) which commonly and/or typically comprises the entire back surface of a common, typical and standard p-i-n or n-i-p junction photovoltaic solar cell device, which may, or may not, incorporate within its matrix, bus-bars and/or electrical leads which are utilized for further connection to an electrical circuit and the transference of positive and/or negative electrical energy from a common, typical and standard p-i-n or n-i-p junction photovoltaic solar cell device. The Magnetic Inducement Layer/Coating (FIG. 3, #47) shall be typically applied to those areas defined as the Application Area (FIG. 6, #71), to within up to one millimeter (1 mm) of the edge of the typical and standard p-i-n or n-i-p junction photovoltaic solar cell device, at a thickness of not less than 50 nanometers (50 nm) and not greater than two centimeters (2 cm), dependent upon the Magnetic Particle Inclusion material's type, geometric structure and/or shape and size.

The drying and/or curing time period requirements of the Magnetic Inducement Layer/Coating (FIG. 3, #47) shall be determined specifically by the Carrier/Binding Medium's (FIG. 3, #48) manufacturer's recommended drying and/or curing period(s), as well as the ambient temperature and/or relative humidity within the application and/or drying and/or curing areas of the production/manufacturing facility(ies).

Turning now to FIG. 4, there is shown a general cross section visual overview which encompasses the summary concept and structure of a magnetically induced multijunction photovoltaic solar cell device. The overall cell configuration is based upon the starting underlying basal structure of a common, typical and standard multijunction photovoltaic solar cell matrix utilizing thin-film technology involving various types of semiconductive materials, including, but not limited to, amorphous silicon (a-Si), and/or germanium (Ge), and/or aluminum-indium-phosphide (AlInP2), and/or aluminum-gallium-indium-arsenide (AlGaInAs), and/or copper-indium-diselenide (commonly known as CIS), and/or copper-indium-gallium-diselenide (commonly known as CIGS), and/or gallium-arsenide (GaAs), and/or gallium-indium-phosphide (GaInP2), and/or cadmium-telluride (CdTe) and/or any combination(s) thereof. Such multijunction photovoltaic solar cell devices are commonly and typically comprised of multiple semiconducting layers consisting of various types of semiconductive materials, including, but not limited to, those semiconductive materials described above, with varying and/or different band-gaps (widest at the top narrowest at the bottom) stacked or cascaded on top of each other and bound together through some form of mechanical means. The most common and typical configuration for these multijunction photovoltaic solar cell devices is outlined within FIG. 4 (a triple junction photovoltaic device), although they are not limited only to this configuration. The FIG. 4 configuration encompasses an antireflective coating (FIG. 4, #50); an electrically conductive grid layer of very thin cross-hatched conductive materials, typically comprised of aluminum (Al) or some form of alloy thereof (FIG. 4, #51); multiple layers of various types of semiconducting materials (FIG. 4, #52), including, but not limited to, any or all of those materials as described above, in various configurations of n-layers (negative doped) and p-layers (positive doped), typically comprised of, but not limited to, an upper negatively charged n-layer (negative doped) of some type of semiconductive material, such as, but not limited to, aluminum-indium-phosphide (AlInP2), a middle negatively charged n-layer (negative doped) of some type of semiconductive material, such as, but not limited to, gallium-indium-phosphide (GaInP2) and a lower positively charged p-layer (positive doped) of some type of semiconductive material, such as, but not limited to, gallium-indium-phosphide (GaInP2), thereby creating an initial wider band-gap photovoltaic solar cell sub-device within the matrix of the overall multijunction photovoltaic solar cell device. The next level is commonly referred to as a diode tunnel (FIG. 4, #53) which is typically comprised of, but not limited to, an upper positively charged p-layer (positive doped) of narrower band-gap type of semiconductive material, such as, but not limited to, gallium-indium-arsenide (GaInAs) and a lower negatively charged n-layer (negative doped) of narrower band-gap semiconductive material, such as, but not limited to, gallium-indium-arsenide (GaInAs) which thereby creates a secondary narrower band-gap photovoltaic solar cell sub-device within the matrix of the overall multijunction photovoltaic solar cell device. The majority of the unabsorbed and/or uncollected high band-gap photons pass through the semiconductive structure of this narrower band-gap diode tunnel and interface with the high band-gap semiconductive sub-layers of the device matrix, or bottom semiconducting layer(s) (FIG. 4, #54), which are typically comprised of, but not limited to, an upper negatively charged n-layer (negative doped) of higher band-gap aluminum-gallium-arsenide (AlGaAs), a middle negatively charged n-layer (negative doped) of higher band-gap gallium-arsenide (GaAs) and a lower positively charged p-layer (positive doped) of higher band-gap semiconductive material, such as, but not limited to, gallium-arsenide (GaAs), which thereby creates an even narrower band-gap photovoltaic solar cell sub-device within the matrix of the overall multijunction photovoltaic solar cell device. The final bottom layer of a standard and typical multijunction photovoltaic solar cell device is a substrate layer (FIG. 4, #55), which is characteristically comprised of, but not limited to, a positively charged p-layer (positive doped) HIGH band-gap semiconductive material, such as, but not limited to, gallium-arsenide (GaAs) which provides the most narrow band-gap photon absorption within the matrix of the overall multijunction photovoltaic solar cell device. An ohmic contact layer (FIG. 4, 56) typically comprised of, but not limited to, aluminum (Al), and/or tin (Sn), and/or copper (Cu), and/or any and all alloys thereof, is typically added for the purpose of positive and or negative electrical energy transference and electrical circuit connection.

The variance from the common, typical and standard multijunction photovoltaic solar cell device matrix is accomplished through the process of applying an additional Magnetic Inducement Layer/Coating (FIG. 4, #57) directly to the back surface area of the Substrate Layer (FIG. 4, #55) and/or the Ohmic Contact Layer (FIG. 4, #56) (dependent upon end use product requirements), of a typical and standard multijunction photovoltaic solar cell device, as described within FIG. 4 above. Such Magnetic Inducement Layer/Coating (FIG. 4, #57) may or may not cover the majority, or the entirety, of the back surface area of such multijunction photovoltaic solar cell device (dependent upon end use product requirements). This Magnetic Inducement Layer/Coating (FIG. 4, #57) may or may not be resistant to heat, i.e. thermally resistant (dependent upon end use product requirements), may or may not be resistant to cold (dependent upon end use product requirements), may or may not be ultra-violet light resistant (dependent upon end use product requirements), may or may not be electrically conductive (dependent upon end use product requirements), shall consist of a Carrier/Binding Medium (FIG. 4, #58) which shall be comprised of, but not limited to, any and all polymers, plastics, epoxies, acrylics, silicones, other synthetics or inks and/or any combination thereof, which provides a carrier vehicle that encapsulates and binds the Magnetic Particle Inclusions (FIG. 4, #59) which shall be in the form of, but not limited to, any and all ferromagnetic materials, any and all rare-earth or lanthanide materials, any and all alnico (aluminum-nickel-cobalt) materials, any and all gallium-manganese-arsenide (GaMnAs) materials, any and all ceramic incorporated/encapsulated variations thereof and/or any and all combination(s) and/or alloys thereof. These Magnetic Particle Inclusions (FIG. 4, #59) shall be comprised of singular and/or multiple, regular and/or irregular, consistent and/or inconsistent geometric shape(s), dependent upon the incorporated material type(s) and/or the end use product requirements. These Magnetic Particle Inclusions (FIG. 4, #59) shall be sized as may be required to facilitate the most efficient and/or available layering and/or coating method(s) as may be reasonably determined based upon the end product requirements and shall range from fifty nanometers (50 nm) up to and including 2 centimeters (2 cm) in size, dependent upon the Magnetic Particle Inclusion's type(s) and/or geometric structure and/or shape, and shall be incorporated and/or dispersed throughout and within said Carrier/Binding Medium (FIG. 4, #58) at a dispersion rate of between twenty-five percent (25%) and sixty percent (60%), by weight and/or volume, dependent upon the inclusion material's type, geometric structure and/or shape, size and end use product requirements.

This Magnetic Inducement Layer/Coating (FIG. 4, #57), inclusive of the Carrier/Binding Medium (FIG. 4, #59) and the Magnetic Particle Inclusions (FIG. 4, #59) shall be applied via overlaying it onto the underlying typical and standard multijunction photovoltaic solar cell device by means of various processing methods, including, but not limited to: a) any and all generally accepted, and/or typical, and/or standard, layering and/or coating application(s) and/or manufacturing process(es), i.e. screen printing, sputtering, spraying, brushing or spreading; and/or b) any and all specialized application and/or manufacturing method(s), and/or means, and/or process(es) as may have been already developed, and/or are yet to be developed, which will expedite the competent and efficient production and/or manufacturing of a magnetically induced multijunction photovoltaic solar cell. Such method(s), and/or means, and/or process(es) shall cause the direct and/or indirect application of the Magnetic Inducement Layer/Coating (FIG. 4, #57) to the non-illuminated side (back) of a common, typical and standard multijunction photovoltaic solar cell device, thereby bonding and/or binding the Carrier/Binding Medium (FIG. 4, #58) and the Magnetic Particle Inclusions (FIG. 4, #59) to such non-illuminated side (back) of a common, typical and standard multijunction photovoltaic solar cell device.

The aforementioned application of the Magnetic Inducement Layer/Coating (FIG. 4, #57) to a common, typical and standard multijunction photovoltaic solar cell device shall be reasonably accomplished consistent and/or pursuant to the outline(s) and diagram(s) provided within FIG. 6, and/or FIG. 7. The Back Surface Area (FIG. 6, #70), references only a portion of the total Underlying Photovoltaic Solar Cell Device Matrix (FIG. 7, #80) which commonly and/or typically comprises the entire back surface of a common, typical and standard multijunction photovoltaic solar cell device, which may, or may not, incorporate within its matrix, bus-bars and/or electrical leads which are utilized for further connection to an electrical circuit and the transference of positive and/or negative electrical energy from a common, typical and standard multijunction photovoltaic solar cell device. The Magnetic Inducement Layer/Coating (FIG. 4, #57) shall be typically applied to those areas defined as the Application Area (FIG. 6, #71), to within up to one millimeter (1 mm) of the edge of the typical and standard multijunction photovoltaic solar cell device, at a thickness of not less than 50 nanometers (50 nm) and not greater than two centimeters (2 cm), dependent upon the Magnetic Particle Inclusion material's type, geometric structure and/or shape and size.

The drying and/or curing time period requirements of the Magnetic Inducement Layer/Coating (FIG. 4, #57) shall be determined specifically by the Carrier/Binding Medium's (FIG. 4, #58) manufacturer's recommended drying and/or curing period(s), as well as the ambient temperature and/or relative humidity within the application and/or drying and/or curing areas of the production/manufacturing facility(ies).

Turning now to FIG. 5, there is shown a schematic diagram and summary representation of the layering/coating application area of a portion of the invention illustrating the surface area of the Magnetic Inducement Layer/Coating pursuant to (FIG. 1, #27), as would be applied to the underlying basal structure of a common, typical and standard homojunction photovoltaic solar cell device.

The Back Surface Area (FIG. 5, #60) references only a portion of the total underlying area which commonly and/or typically comprises the entire back surface of a common, typical and standard homojunction photovoltaic solar cell device, whose BSF (FIG. 1, #26) incorporates within it bus-bars (FIG. 5, #62 and #64) which are utilized for further connection to an electrical circuit and the transference of the electrical energy from a common, typical and standard homojunction photovoltaic solar cell device. The Magnetic Inducement Layer/Coating (FIG. 1, #27) shall be typically applied to those areas defined as the Application Areas (FIG. 5, #61 and #63 and #65) at a thickness of not less than 50 nanometers (50 nm) and not greater than two centimeters (2 cm), dependent upon the inclusion material's type, geometric shape and size. Such application shall typically be continual from within up to one millimeter (1 mm) of the outer edge(s), extending from any and/or all said outer edge(s) across the entire area of said back surface of a common, typical and standard homojunction photovoltaic solar cell and to within up to one millimeter (1 mm) of each and/or all back surface bus-bar(s) (FIG. 5, #62 and #64) contained therein and/or thereon, as is visually represented within FIG. 5, #61 and #63 and #65.

Turning now to FIG. 6, there is shown a schematic diagram and summary representation of the layering/coating application area of a portion of the invention illustrating the surface area for the Magnetic Inducement Layer/Coating pursuant to (FIG. 2, #36), and/or (FIG. 3, #47), and/or (FIG. 4, #57), as would be applied to the underlying basal structure of a common, typical and standard thin-film photovoltaic solar cell device, including, but not limited to, those described within (FIG. 2), and/or (FIG. 3), and/or (FIG. 4).

The Back Surface Area (FIG. 6, #70) references only a portion of the total underlying area which commonly and/or typically comprises the entire back surface of a common, typical and standard thin-film photovoltaic solar cell device, without reference to any bus-bars, and/or electrical leads which are utilized for further connection to an electrical circuit and the transference of the electrical energy from a common, typical and standard thin-film photovoltaic solar cell device. The Magnetic Inducement Layer/Coating pursuant to (FIG. 2, #36), and/or (FIG. 3, #47), and/or (FIG. 4, #57); which is comprised of the Carrier/Binding Medium pursuant to (FIG. 2, #37), and/or (FIG. 3, #48), and/or (FIG. 4, #58); and the Magnetic Particle Inclusions pursuant to (FIG. 2, #38), and/or (FIG. 3, #49) and/or (FIG. 4, #59), shall be typically applied to those areas defined as the Application Area (FIG. 6, #71) at a thickness of not less than 50 nanometers (50 nm) and not greater than two centimeters (2 cm), dependent upon the inclusion material's type, geometric shape and size. Such application shall typically be continual from within up to one millimeter (1 mm) of the outer edge(s), extending from any and/or all said outer edge(s) across the entire area of said back surface area of a common, typical and standard thin-film photovoltaic solar cell device.

Turning now to FIG. 7, there is shown an elevational view of the invention based upon the underlying basal structure of any and all photovoltaic solar cell device types providing a visualization of the side view of a Magnetically Induced Photovoltaic Solar Cell Device showing a representation of the full width view of the underlying photovoltaic solar cell device (FIG. 7, #80) (any and all types) and a representation of the full width view of the Magnetic Inducement Layer/Coating (FIG. 7, #81), and/or (FIG. 1, #27), and/or (FIG. 2, #36), and/or (FIG. 3, #47), and/or (FIG. 4, #57); each of which is comprised of the Carrier/Binding Medium (FIG. 1, #28), and/or (FIG. 2, #37), and/or (FIG. 3, #48), and/or (FIG. 4, #58); and the Magnetic Particle Inclusions (FIG. 1, #29), and/or (FIG. 2, #38), and/or (FIG. 3, #49) and/or (FIG. 4, #59).

While the invention has been described in connection with a preferred embodiment, it is not intended to limit the scope of the invention to the particular form set forth, but on the contrary, it is intended to cover such alternatives, modifications, and equivalents as may be included within the spirit and scope of the invention as defined by the appended claims.

What is claimed is:

1. An article of manufacture for a magnetically induced photovoltaic solar cell device and the process for creating the magnetic and/or electromagnetic field comprising:
a basal underlying structure consisting of the body of a photovoltaic solar cell device which is comprised of, but not limited to, conductive materials such as aluminum (Al), silver (Ag), tin (Sn), copper (Cu), zinc (Zn), ferrites (Fe) (all variations) as well as any and all other conductive materials which have been, or may be in the future, determined to be of beneficial interest to the photovoltaic industry;
a basal underlying structure consisting of the body of a photovoltaic solar cell device which is comprised of, but not limited to, semiconductive materials such as silicon (Si) (all variations), sulfur and/or sulfides (S), copper (Cu), indium (In), gallium (Ga), arsenide (As), germanium (Ge), cadmium (Cd), tellurium or tellurides (Te), and/or any combinations thereof, as well as any and all other semiconductive materials which have been, or may be in the future, determined to be of beneficial interest to the photovoltaic industry, and/or any combinations thereof;
a basal underlying structure consisting of the body of a photovoltaic solar cell device which is comprised of, but not limited to, a protective glass cover, an antireflective coating, a front surface field (FSF), a negatively charged n-layer, a positively charged p-layer, a p-n junction area, a back surface field (BSF) and bus-bars within the BSF;
a basal underlying structure consisting of the body of a photovoltaic solar cell device which is comprised of, but not limited to, a transparent conducting layer, an antireflective coating, a “window” layer (a negatively charged n-layer), an absorptive layer (a positively charged p-layer), an ohmic contact layer, and a substrate layer;
a basal underlying structure consisting of the body of a photovoltaic solar cell device which is comprised of, but not limited to, a transparent conducting layer, an antireflective coating, an upper positively charged layer (p-layer) or an upper negatively charged layer (n-layer), an intrinsic/resistive layer, a lower positively charged layer (p-layer) or a lower negatively charged layer (n-layer), an ohmic layer and a substrate layer;
a basal underlying structure consisting of the body of a photovoltaic solar cell device which is comprised of, but not limited to, an antireflective coating, a conductive grid layer, a top section of multiple layers of semiconducting materials (either positively charged p-type, or negatively charged n-type, or both), a middle section of multiple layers of semiconducting materials (either positively charge p-type, or negatively charged n-type, or both), a bottom section of multiple layers of semiconducting materials (either positively charged p-type, or negatively charged n-type, or both) and a substrate layer (which may or may not be another semiconducting layer);
an overlaying magnetic inducement layer and/or coating comprised of a carrier/binding medium and magnetic particle inclusions;
a carrier/binding medium comprised of but not limited to, polymers, plastics, epoxies, acrylics, silicones, other synthetic materials and inks, and/or any combination thereof, as as well as any and all other carrier/binding materials which have been, or may be in the future, determined to be of beneficial interest to the photovoltaic industry; and
magnetic particle inclusions, as contained within the carrier/binding medium, in the form of, but not limited to, all ferromagnetic materials (Fe) (and all variations thereof), all rare-earth or lanthanide materials, aluminum (Al) (and all variations thereof), nickel (Ni) (and all variations thereof), cobalt (Co) (and all variations thereof), gallium (Ga), magnesium (Mn), arsenide (As), and/or any and all ceramic variations thereof, and/or any and combinations or alloys thereof.

2. A process for a magnetically induced photovoltaic solar cell device and the process for creating the magnetic and/or electromagnetic field comprising the steps of:
a basal underlying structure consisting of the body of a photovoltaic solar cell device which is comprised of, but not limited to, conductive materials such as aluminum (Al), silver (Ag), tin (Sn), copper (Cu), zinc (Zn), ferrites (Fe) (all variations) as well as any and all other conductive materials which have been, or may be in the future, determined to be of beneficial interest to the photovoltaic industry;
a basal underlying structure consisting of the body of a photovoltaic solar cell device which is comprised of, but not limited to, semiconductive materials such as silicon (Si) (all variations), sulfur and/or sulfides (S), copper (Cu), indium (In), gallium (Ga), arsenide (As), germanium (Ge), cadmium (Cd), tellurium or tellurides (Te), and/or any combinations thereof, as well as any and all other semiconductive materials which have been, or may be in the future, determined to be of beneficial interest to the photovoltaic industry, and/or any combinations thereof;
a basal underlying structure consisting of the body of a photovoltaic solar cell device which is comprised of, but not limited to, a protective glass cover, an antireflective coating, a front surface field (FSF), a negatively charged n-layer, a positively charged p-layer, a p-n junction area, a back surface field (BSF) and bus-bars within the BSF;
a basal underlying structure consisting of the body of a photovoltaic solar cell device which is comprised of, but not limited to, a transparent conducting layer, an antireflective coating, a “window” layer (a negatively charged n-layer), an absorptive layer (a positively charged p-layer), an ohmic contact layer, and a substrate layer;
a basal underlying structure consisting of the body of a photovoltaic solar cell device which is comprised of, but not limited to, a transparent conducting layer, an antireflective coating, an upper positively charged layer (p-layer) or an upper negatively charged layer (n-layer), an intrinsic/resistive layer, a lower positively charged layer (p-layer) or a lower negatively charged layer (n-layer), an ohmic layer and a substrate layer;
a basal underlying structure consisting of the body of a photovoltaic solar cell device which is comprised of, but not limited to, an antireflective coating, a conductive grid layer, a top section of multiple layers of semiconducting materials (either positively charged p-type, or negatively charged n-type, or both), a middle section of multiple layers of semiconducting materials (either positively charge p-type, or negatively charged n-type, or both), a bottom section of multiple layers of semiconducting materials (either positively charged p-type, or negatively charged n-type, or both) and a substrate layer (which may or may not be another semiconducting layer);
overlaying and/or coating the basal underlying structure, consisting of photovoltaic solar cell device, with a magnetic inducement layer and/or coating comprised of a carrier/binding medium and magnetic particle inclusions;
the utilization of a carrier/binding medium comprised of, but not limited to, polymers, plastics, epoxies, acrylics, silicones, other synthetic materials and inks, and/or any combination thereof, as as well as any and all other carrier/binding materials which have been, or may be in the future, determined to be of beneficial interest to the photovoltaic industry; and
the utilization of magnetic particle inclusions, as contained within the carrier/binding medium, in the form of, but not limited to, all ferromagnetic materials (Fe) (and all variations thereof), all rare-earth or lanthanide materials, aluminum (Al) (and all variations thereof), nickel (Ni) (and all variations thereof), cobalt (Co) (and all variations thereof), gallium (Ga), magnesium (Mn), arsenide (As), and/or any and all ceramic variations thereof, and/or any and combinations or alloys thereof.
